(19) United States
(12) Patent Application Publication
(10) Pub. No.: US 2016/0014897 A1
(43) Pub. Date: Jan. 14, 2016

(54) POWER SEMICONDUCTOR MODULE

(71) Applicant: Danfoss Silicon Power GmbH, Flensburg (DE)

(72) Inventors: Henning Ströbel-Maier, Kiel (DE); Christian Aggen, Flensburg (DE)

(21) Appl. No.: 14/664,175

(22) Filed: Mar. 20, 2015

(30) Foreign Application Priority Data
Apr. 3, 2014 (EP) 102014104716.8

(51) Int. Cl. H05K 1/14; H01L 25/07; H05K 1/18

(52) U.S. Cl. CPC H05K 1/142; H05K 1/141; H05K 1/18; H01L 25/072; H05K 2201/10272; H05K 2201/10522

(57) ABSTRACT

Power semiconductor module (10, 10′) comprising at least four substrates (DCB1, DCB2, DCB3, DCB4, DCB5, DCB6) disposed on a baseplate (20), each having a first connection point for a higher potential (a) and a second connection point for a lower potential (b), and comprising a first busbar (30) connected to the first connection points for the higher potential (a) and a second busbar (40) connected to the second connection points for the lower potential (b), characterized in that the order of the connection points (b, a) of at least one substrate (DCB4) differs from the order of the connection points (a, b) of the other substrates (DCB1, DCB2, DCB3, DCB5, DCB6).

### CROSS REFERENCE TO RELATED APPLICATIONS

Applicant hereby claims foreign priority benefits under U.S.C. §119 from German Patent Application No. DE102014104716.8 filed on Apr. 3, 2014, the contents of which are incorporated by reference herein.

### TECHNICAL FIELD

The invention relates to a power semiconductor module comprising at least four substrates disposed on a baseplate, each having a first connection point for a lower potential and a second connection point for a higher potential, and comprising a first busbar connected to the first connection points for the lower potential and a second busbar connected to the second connection points for the higher potential.

### BACKGROUND

Such a power semiconductor module is known, for example, from DE 10 2006 004 031 B3, wherein the object of this invention was to improve the balancing of the load currents as well in addition to reducing the module inductance by virtue of the “main current flow directions” being designed uniformly by tapping off the positive and negative voltage potential on the substrates in each case in identical order.

The object of the invention consists in further improving the balancing of the current distributions for dynamic processes and in particular in reducing, in a targeted manner, the loading of individual switches in the event of a short circuit.

### SUMMARY

This object is achieved by the power semiconductor module comprising at least four substrates (DCB1, DCB2, DCB3, DCB4, DCB5, DCBE) disposed on a baseplate, each having a first connection point for a higher potential (a) and a second connection point for a lower potential (b), and a first busbar connected to the first connection points for the higher potential (a) and a second busbar connected to the second connection points for the lower potential (b), wherein the order of the connection points (b, a) of at least one substrate (DCB4) differs from the order of the connection points (a, b) of the other substrates (DCB1, DCB2, DCB3, DCB5, DCBE).

In tests with respect to the subject matter mentioned at the outset, owing to the mirroring of substrates and therefore owing to the change to the previously known order of potential taps on the substrates, it became apparent that an improvement in the current balancing is effected in the event of an overload or the case of a short circuit owing to the arrangement with a mirrored substrate. Precisely on the particularly critical high side of the half-bridge circuit, a marked reduction in the unequal distribution of the currents is achieved, and therefore the overload on the individual semiconductor switches is reduced.

Contrary to general assumptions, not only optimizations of the individual current paths of each substrate are important, but primarily matching of the current paths to the load current busbars which are unbalanced owing to design in power modules. An unbalanced busbar generally results in the load current flowing through the module with a main current flow direction in the direction of the DCB arrangement and effects parasitic couplings of different intensity on the individual substrates. Owing to these couplings on the busbar, in turn imbalances of the current distribution are brought about in the case of dynamic processes. These can be compensated for by targeted changes to the arrangement of individual substrates. In the event of a short circuit on the high side, the short-circuit current and therefore the risk of destruction could be markedly reduced without restricting the actual function of the module.

### BRIEF DESCRIPTION OF THE DRAWINGS

The invention will be explained in more detail with reference to an exemplary embodiment with a particularly preferred configuration as illustrated in the attached drawings, in which:

FIG. 1 shows a perspective view of a power semiconductor module with a particularly preferred configuration;

FIG. 2 shows a plan view of the power semiconductor module from FIG. 1 without busbars;

FIG. 3 shows a plan view of the power semiconductor module from FIG. 1 with busbars;

FIG. 4 shows a comparison of the short-circuit current level between a known power semiconductor module IFX and the power semiconductor module DSP configured in accordance with the invention;

FIG. 5 shows a comparison of the DCB current distribution between the power semiconductor module IFX known from DE 10 2006 004 031 B3 and the power semiconductor module DSP with a configuration in accordance with the invention in the case of a short circuit on the high side; and

FIG. 6 shows a plan view of a further power semiconductor module in accordance with the invention.

### DETAILED DESCRIPTION

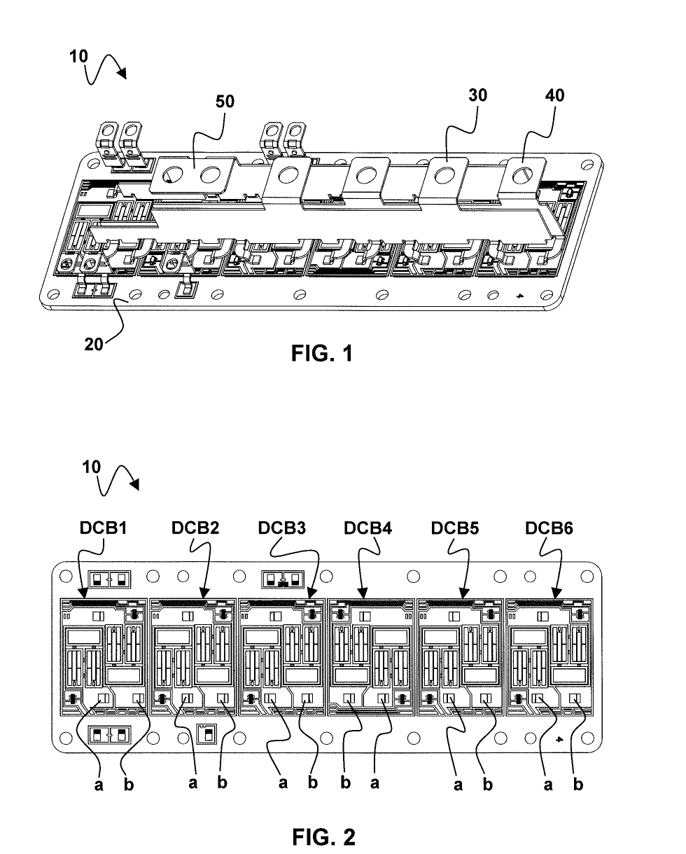

FIG. 1 shows a perspective view of a power semiconductor module with a particularly preferred configuration. The power semiconductor module 10 has a baseplate 20 provided with a plurality of substrates and busbars 30, 40, 50 connected to the substrates.

The precise arrangement of the substrates, which is preferably in a single row, can be seen from the plan view of the power semiconductor module 10 illustrated in FIG. 2, in which the busbars 30, 40, 50 have been omitted for clearer illustration. In accordance with the invention, at least four substrates DCB1, DCB2, DCB3, DCB4, DCB5, DCB6 disposed on the baseplate 20 are provided. The six substrates DCB1, DCB2, DCB3, DCB4, DCB5, DCB6 shown here, which preferably have parallel-connected half-bridge circuits, each have a first connection point for a higher potential a and a second connection point for a lower potential b, wherein the connection points for the higher potential a are electrically connected to one busbar 30 and the connection points for the lower potential b are electrically connected to the other busbar 40.

The order of the connection points a, b is now, in accordance with the invention, not identical for all substrates DCB1, DCB2, DCB3, DCB4, DCB5, DCB6, but is designed in such a way that the order of the connection points a, b of at least one substrate, namely of the substrate denoted here by the reference symbol “DCB4”, differs from the order of the connection points a, b of the other substrates DCB1, DCB2, DCB3, DCB5, DCB6. In particular, the order of the connection points b, a of the substrate DCB4 is opposite the order of the connection points a, b of the other substrates, i.e. is the reverse order.

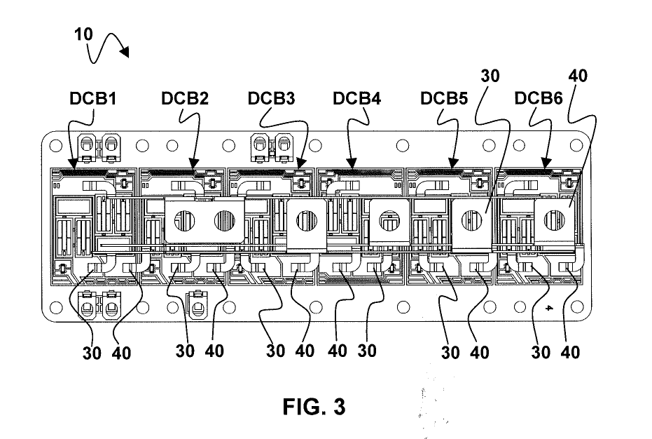

Correspondingly, as shown in plan view in FIG. 3, the connection order of the inner connections of the busbars 30, 40 is also not purely repetitive, but deviates for the substrate denoted by “DCB4”. As known, the busbars 30, 40 preferably have outer connections leading away from the substrates DCB1, DCB2, DCB3, DCB4, DCB5, DCB6.

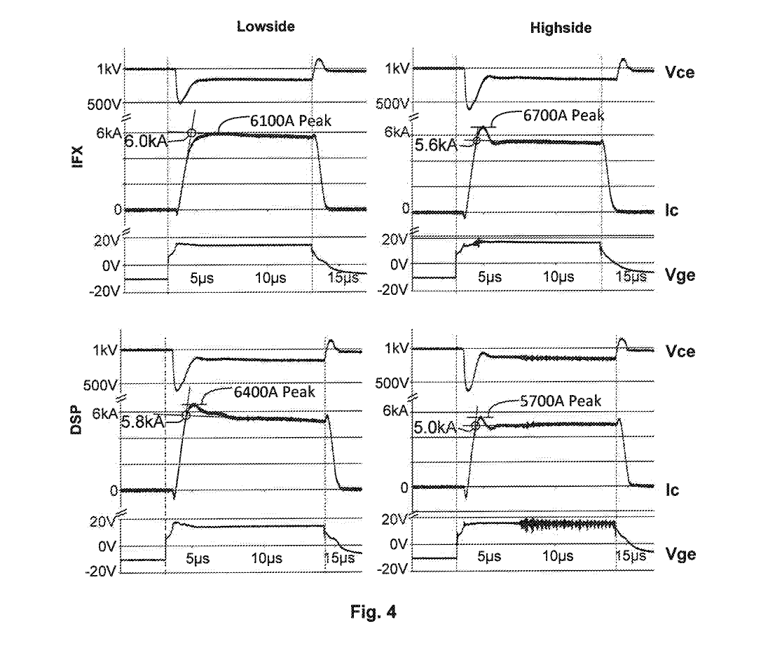

FIG. 4 now shows a comparison of the short-circuit current levels between the power semiconductor module IFX known from DE 10 2006 004 031 B3 and the power semiconductor module DSP configured in accordance with the invention. It can be read from the point of intersection marked in the circle that the short-circuit current level on the high side of the power semiconductor module DSP configured in accordance with the invention is markedly reduced in comparison with the known module IFX.

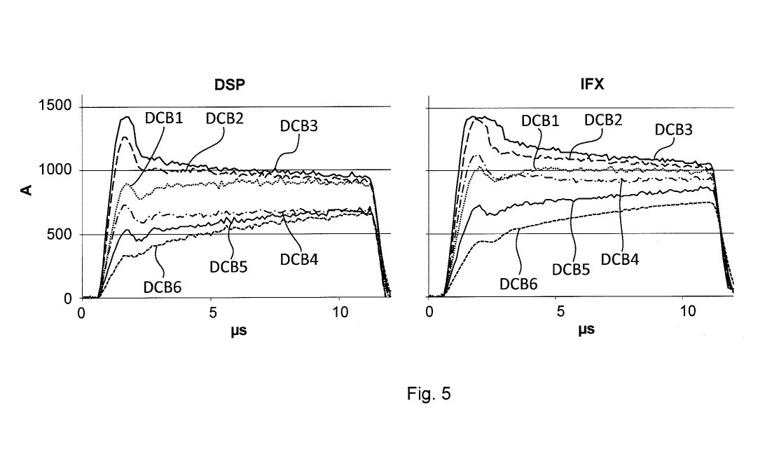

FIG. 5 shows a comparison of the DCB current distribution between the power semiconductor module IFX known from DE 10 2006 004 031 B3 and the power semiconductor module DSP configured in accordance with the invention. It can clearly be seen that a short circuit on the DCB plane is less critical for the power semiconductor module 10 configured in accordance with the invention since the duration of the current peak is shorter. In addition, a markedly improved distribution of the currents between the individual substrates DCB1, DCB2, DCB3, DCB4, DCB5, DCBE is achieved.

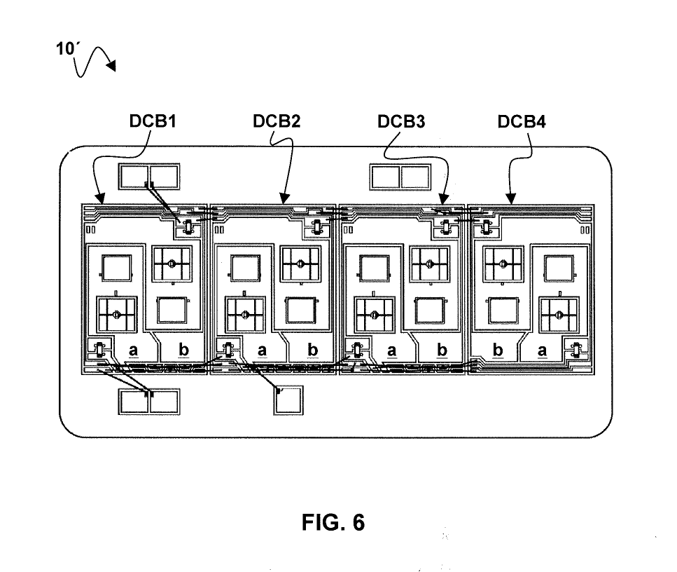

Finally, FIG. 6 shows a plan view of a further power semiconductor module 10′ in accordance with the invention, in which only four substrates DCB1, DCB2, DCB3, DCB4 are provided. In accordance with the invention, in this case the order of the connection points b, a of the substrate DCB4 differs from the order of the connection points a, b of the other substrates DCB1, DCB2, DCB3.

While the present invention has been illustrated and described with respect to a particular embodiment thereof, it should be appreciated by those of ordinary skill in the art that various modifications to this invention may be made without departing from the spirit and scope of the present.

What is claimed is:

1. A power semiconductor module comprising
at least four substrates (DCB1, DCB2, DCB3, DCB4, DCB5, DCB6) disposed on a baseplate, each having a first connection point for a higher potential (a) and a second connection point for a lower potential (b), and
a first busbar connected to the first connection points for the higher potential (a) and a second busbar connected to the second connection points for the lower potential (b),
characterized in that wherein
the order of the connection points (b, a) of at least one substrate (DCB4) differs from the order of the connection points (a, b) of the other substrates (DCB1, DCB2, DCB3, DCB5, DCB6).

2. The power semiconductor module according to claim 1, wherein the order of the connection points (a, b) of the at least one substrate (DCB4) is opposite the order of the connection points (a, b) of the other substrates (DCB1, DCB2, DCB3, DCB5, DCB6).

3. The power semiconductor module according to claim 1, wherein the busbars have outer connections leading away from the substrates (DCB1, DCB2, DCB3, DCB4, DCB5, DCBE).

4. The power semiconductor module according to claim 1, wherein the substrates (DCB1, DCB2, DCB3, DCB4, DCB5, DCB6) have parallel-connected half-bridge circuits.

5. The power semiconductor module according to claim 1, wherein the substrates (DCB1, DCB2, DCB3, DCB4, DCB5, DCB6) are arranged in a row.

6. The power semiconductor module according to claim 2, wherein the busbars have outer connections leading away from the substrates (DCB1, DCB2, DCB3, DCB4, DCB5, DCB6).

7. The power semiconductor module according to claim 2, wherein the substrates (DCB1, DCB2, DCB3, DCB4, DCB5, DCB6) have parallel-connected half-bridge circuits.

8. The power semiconductor module according to claim 3, wherein the substrates (DCB1, DCB2, DCB3, DCB4, DCB5, DCB6) have parallel-connected half-bridge circuits.

9. The power semiconductor module according to claim 2, wherein the substrates (DCB1, DCB2, DCB3, DCB4, DCB5, DCB6) are arranged in a row.

10. The power semiconductor module according to claim 3, wherein the substrates (DCB1, DCB2, DCB3, DCB4, DCB5, DCB6) are arranged in a row.

11. The power semiconductor module according to claim 4, wherein the substrates (DCB1, DCB2, DCB3, DCB4, DCB5, DCB6) are arranged in a row.
